(19) United States
(12) Patent Application Publication
(10) Pub. No.: US 2004/0259321 A1
(43) Pub. Date: Dec. 23, 2004

(54) Reducing processing induced stress

(76) Inventors: Mehran Aminzadeh, Saratoga, CA (US); Sergei Koveshnikov, Hillsboro, OR (US)

Correspondence Address: Timothy N. Trop, TROP, PRUNER & HU, P.C., STE 100, 8554 KATY FWY, HOUSTON, TX, 77024-1841, US

(21) Appl. No.: 10/465,212

(22) Filed: Jun. 19, 2003

(51) Int. Cl. H01L 21/76

(52) U.S. Cl. 438/424; 438/795

(57) ABSTRACT

By providing a thermal protocol that involves two steps prior to any isolation steps in a metal oxide semiconductor process, induced stress may be reduced between the bulk silicon and overlying areas, such as epitaxial layers. As a result, the dislocations in the overlying area may be reduced.

### BACKGROUND

This invention relates generally to fabrication techniques for forming components of integrated circuits, such as metal oxide semiconductor field effect transistors.

Process induced stress may occur in an active area of an integrated circuit. One example of such stress occurs between the bulk silicon substrate and an overlying epitaxial layer. In other cases, process induced stress may occur between any layer overlying a bulk silicon substrate.

During processing and thereafter, internal stresses may develop as a result of the different characteristics of the silicon substrate and overlying areas. The existing process steps, such as shallow trench isolation processes, oxide and nitride film deposition, and well implantation, to mention a few examples, induce tensile and/or compressive stresses on the resulting devices. These stresses can result in silicon dislocation in the active device areas.

Another important import issue in fabrication of high quality integrated circuits is contamination with metallic impurities such as copper, nickel, iron and others. The stress-induced dislocations may increase a leakage current. If the dislocations are decorated with metallic impurities they can cause detrimental degradation of the device performance.

Thus, there is a need for ways to reduce the stress that is induced in processing. Also, there is a need to reduce concentrations of metallic impurities in the active device area.

### BRIEF DESCRIPTION OF THE DRAWINGS

FIG. 1 is an enlarged, schematic cross-sectional view of one embodiment of the present invention.

### DETAILED DESCRIPTION

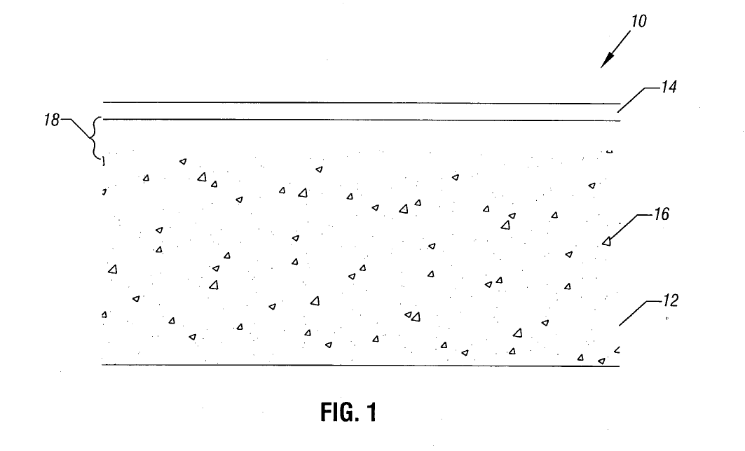

Referring to FIG. 1, a wafer 10 may have an overlying active device layer 14. In one embodiment, the layer 14 may be an epitaxial layer but, in other embodiments, the layer can be virtually anything including metal, dielectric, conductive and non-conductive layers, and combinations thereof. The wafer 10 may include a plurality of nuclei 16 that have formed at a region below the surface of the substrate. A region 18 that is substantially free of nuclei exists near the surface. In one embodiment, the region 18 may extend to a depth of approximately 5 microns or more.

The nuclei 16 may be formed by appropriately preparing the silicon ingot and thereafter following a desired thermal processing protocol. In general, it is desirable to increase the oxygen precipitate formation rate. One way to do this is to dope the silicon by using a nitrogen or carbon atmosphere when the silicon ingot is being formed.

Thereafter, the wafer 10 may be processed using a thermal protocol having two stages. In a first stage, the wafer 10 is exposed to a temperature of between about 650° to about 850° C. This first stage is followed by a high temperature anneal at a temperature in the range of about 950° to about 1050° C. The first stage is effective to create nucleation sites and the second thermal stage is effective to induce the growth of those nucleation sites. As used herein, nucleation refers to the initial stage of phase transformation, indicated by small particles or nuclei of the new phase being formed within the old phase. These nuclei are able to subsequently grow during the second thermal processing stage. Thus, the first stage of the thermal processing is responsible for creating the nuclei and the second stage is responsible for causing them to grow. At the first stage a wafer may alternatively obtain slow heating (1 to 1.5 degree/min) from about 600° C. up to the annealing temperature used at the second stage.

As a result of the thermal processing, oxygen precipitates and stacking faults or dislocations are formed in the bulk silicon wafer 10 to lower the differential in mechanical strength of the active device layer 14 versus the bulk wafer. One factor that causes internal stress is higher oxygen concentration in the substrate and the lower oxygen concentration in the layer 14. Creation of oxygen precipitates and stacking faults in the bulk silicon reduces the yield strength of bulk silicon wafers, therefore allowing the layer 14 to have greater relative strength and higher tolerance to process induced stress.

The process induced stresses may arise as a result of shallow trench isolation, oxide and nitride films, and implant processing steps. Effectively, built in intrinsic gettering is achieved by the two-stage thermal process wherein the first stage involves the nucleation of interstitial oxygen in Czchrolaski grown silicon crystals. The heating processes may be done in a furnace or using rapid thermal processing. The initial stage may be followed by high temperature anneal to induce growth of the bulk defects.

The two-stage thermal protocol may be implemented prior to the initiation of isolation steps, such as the formation of a shallow trench isolation. This ensures that the ability to withstand process induced stress is achieved prior to the most likely cause of that stress.

In some embodiments of the present invention, the temperature processing should be implemented for a time to create oxygen precipitates and stacking faults at a density higher than about 10⁵ and most advantageously about 10⁶ defects per square centimeter in the bulk silicon. The creation of the region 18 reduces device performance issues from these nuclei.

The silicon substrate with moderate levels of interstitial oxygen has higher mechanical strength than the layer 14 that has no oxygen. Therefore, when various process steps, such as isolation, dielectric film deposition, and implants introduce stress in the active area of the wafer, dislocations will be experienced. The use of the thermal processing protocol transforms the interstitial oxygen in the bulk silicon into SiOX precipitates thus reducing the mechanical strength differential between the layer 14 and the substrate and help to relieve the process induced stress to the substrate rather than the forming of dislocations in the layer 14.

As a result, in some embodiments, higher process induced stress tolerance in the active area may be achieved. Bulk defect sites may be provided for gettering of metallic impurities independently of process thermal budget.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
exposing a silicon wafer to a thermal protocol involving a first stage in which the wafer is subjected to a temperature of from about 600° to about 850° C. followed by a second stage in which the wafer is subjected to a temperature of from about 950° to about 1050° C.; and
exposing said silicon wafer to a gaseous environment that increases the oxygen formation rate relative to ambient.

2. The method of claim 1 including exposing the wafer to a first stage for an amount of time sufficient to create nucleation sites for precipitation of oxygen in the second stage.

3. The method of claim 2 including continuing said first stage until 10⁵ to 10⁶ defects per square centimeter.

4. The method of claim 1 including heating using a furnace.

5. The method of claim 1 including heating using rapid thermal processing.

6. The method of claim 1 including, in said first stage, heating from about 600° C. up to the temperature used in the second stage.

7. The method of claim 6 including heating from about 600° C. at a rate of 1 to 1.5 degrees per minute.

8. The method of claim 1 including forming a region substantially free of nuclei at the surface of said wafer.

9. The method of claim 8 including forming a substantially nuclei free region to a depth of approximately 5 microns.

10. The method of claim 1 including forming the wafer from an ingot processed to increase the silicon oxygen precipitation formation rate.

11 (Canceled).

12. The method of claim 1 including exposing said silicon to at least one of nitrogen or carbon.

13. The method of claim 1 including heating the wafer in the first and second stages in an atmosphere containing about 98 percent nitrogen.

14. (canceled).

15. (canceled).

16. (canceled).

17. (canceled).

18. (canceled).

19-22. (Canceled).
